(19) United States
(12) Patent Application Publication
(10) Pub. No.: US 2014/0110771 A1
(43) Pub. Date: Apr. 24, 2014

(54) SOLID-STATE IMAGING DEVICE AND SEMICONDUCTOR DEVICE

(71) Applicant: KABUSHIKI KAISHA TOSHIBA, Minato-ku (JP)

(72) Inventors: Tomoyuki YODA, Kawasaki-shi (JP); Jiro Hayakawa, Inagi-shi (JP); Ikuko Inoue, Yokohama-shi (JP); Eiji Sato, Kawasaki-shi (JP); Takeshi Kitahara, Kawasaki-shi (JP)

(73) Assignee: KABUSHIKI KAISHA TOSHIBA, Minato-ku (JP)

(21) Appl. No.: 13/948,600

(22) Filed: Jul. 23, 2013

(30) Foreign Application Priority Data
Oct. 19, 2012 (JP) 2012-232194

(51) Int. Cl. H01L 31/0224

(52) U.S. Cl. CPC H01L 31/0224
USPC 257/290

(57) ABSTRACT

According to one embodiment, a solid-state imaging device includes a semiconductor substrate including a pixel area and a peripheral circuit area, a first line provided in the peripheral circuit area and on a first principal surface of the semiconductor substrate, a second line provided in the peripheral circuit area and on a second principal surface of the semiconductor substrate, a first through electrode connected to one end of the first line and one end of the second line and passing through the semiconductor substrate, and a second through electrode connected to the other end of the first line and the other end of the second line and passing through the semiconductor substrate.

### CROSS-REFERENCE TO RELATED APPLICATIONS

This application is based upon and claims the benefit of priority from Japanese Patent Application No. 2012-232194, filed Oct. 19, 2012, the entire contents of which are incorporated herein by reference.

### FIELD

Embodiments described herein relate generally to a solid-state imaging device and a semiconductor device.

### BACKGROUND

Solid-state imaging devices such as a CCD image sensor and a CMOS image sensor are used in, for example, a digital camera, a video camera and a surveillance camera for various purposes. To address a decrease in pixel size, some of the solid-state imaging devices employ a backside illumination structure that is advantageous for securing an amount of light incident upon a photodiode. A backside illumination solid-state imaging device can be improved in sensitivity and image quality because it excludes an optical obstacle such as a metal interconnection between a light-receiving area and microlenses.

The backside illumination solid-state imaging device comprises a pixel area including light-receiving elements and a peripheral circuit. The peripheral circuit is arranged like, for example, a ring around the pixel area and include a logic circuit and an analog circuit. If a peripheral circuit area is decreased in width to miniaturize the device, it is lengthened, which makes it difficult to provide lines, especially power lines in the peripheral circuit. Thus, the power lines increase in resistance and the power drop of the device becomes great, with the result that the power of the device becomes unstable.

### BRIEF DESCRIPTION OF THE DRAWINGS

FIG. 1 is a layout of the front side of a solid-state imaging device according to a first embodiment;

FIG. 2 is a layout of the backside of the solid-state imaging device;

FIG. 3 is a sectional view of the solid-state imaging device taken along line A-A′ of FIGS. 1 and 2;

FIG. 4 is a sectional view of the solid-state imaging device taken along line B-B′ of FIGS. 1 and 2;

FIG. 5 is a layout showing a front side interconnection layer in detail;

FIG. 6 is a sectional view of the front side interconnection layer taken along line C-C′ of FIG. 5;

FIG. 7 is a sectional view of a peripheral circuit area of a solid-state imaging device according to a second embodiment;

FIG. 8 is a layout of the backside of a solid-state imaging device according to a third embodiment; and

FIG. 9 is a block diagram of a digital camera using the solid-state imaging device according to the embodiment.

### DETAILED DESCRIPTION

In general, according to one embodiment, there is provided a solid-state imaging device comprising:

a semiconductor substrate including a pixel area and a peripheral circuit area and having a first principal surface and a second principal surface;

a first line provided in the peripheral circuit area and on the first principal surface of the semiconductor substrate and extending in a first direction;

a second line provided in the peripheral circuit area and on the second principal surface of the semiconductor substrate and extending in the first direction;

a first through electrode connected to one end of the first line and one end of the second line and passing through the semiconductor substrate; and

a second through electrode connected to the other end of the first line and the other end of the second line and passing through the semiconductor substrate.

Embodiments will be explained below with reference to the accompanying drawings. Note that these drawings are exemplary or conceptual, so the dimensions and ratios of each drawing are not necessarily the same as real dimensions and ratios. Several embodiments to be described below represent examples of apparatuses and methods for embodying the technical idea of the present invention, and the technical idea of the present invention is not specified by the shapes, structures, and layouts of the constituent parts. Note that in the following explanation, the same reference numerals denote elements having the same functions and arrangements, and a repetitive explanation will be made only when necessary.

### First Embodiment

In the first embodiment, a CMOS image sensor having a backside illumination (BSI) structure will be described as an example of a solid-state imaging device.

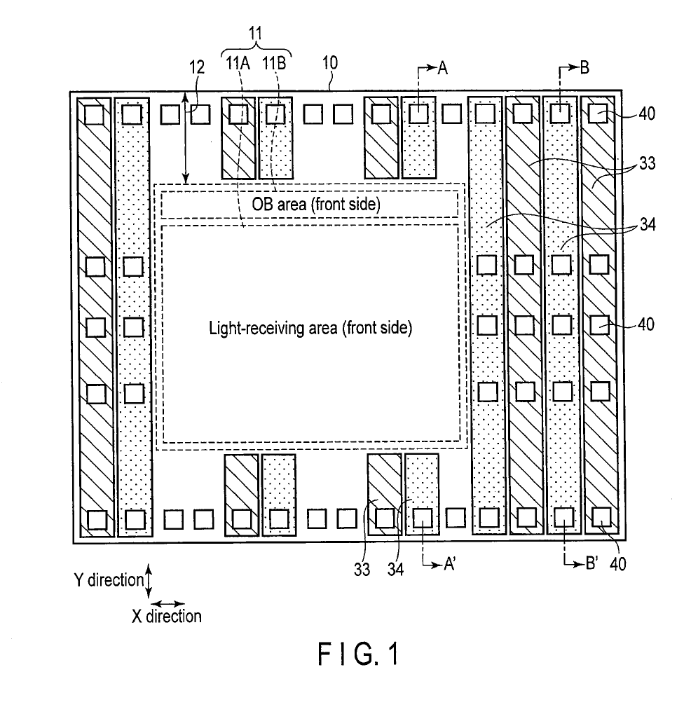

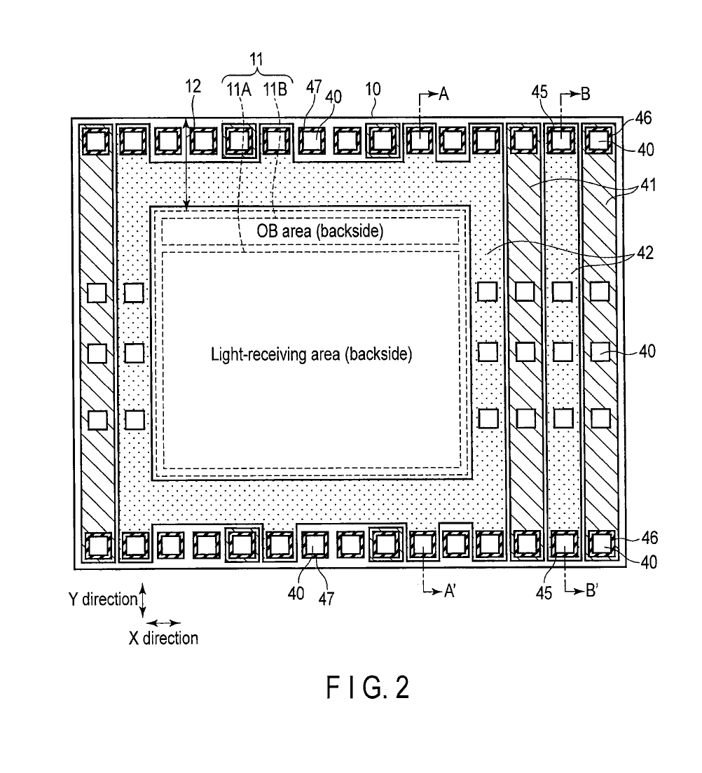

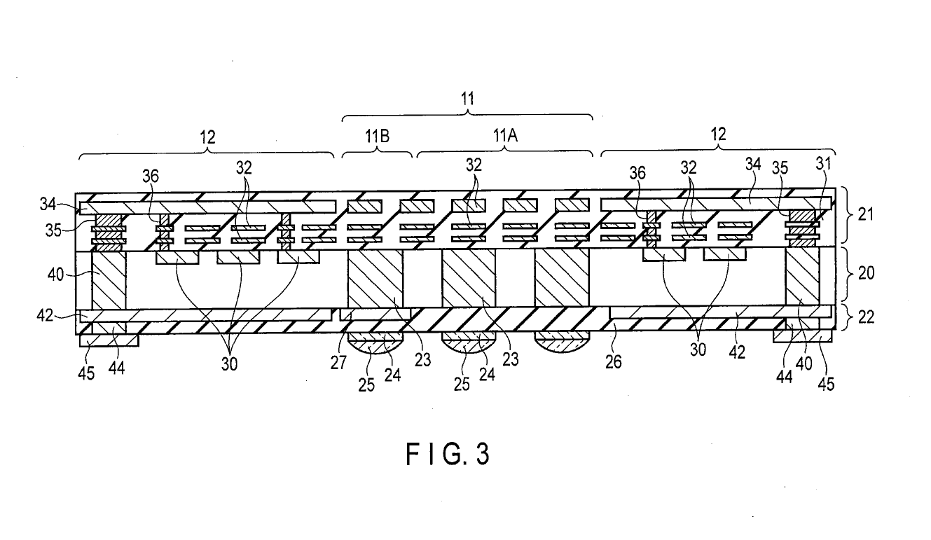

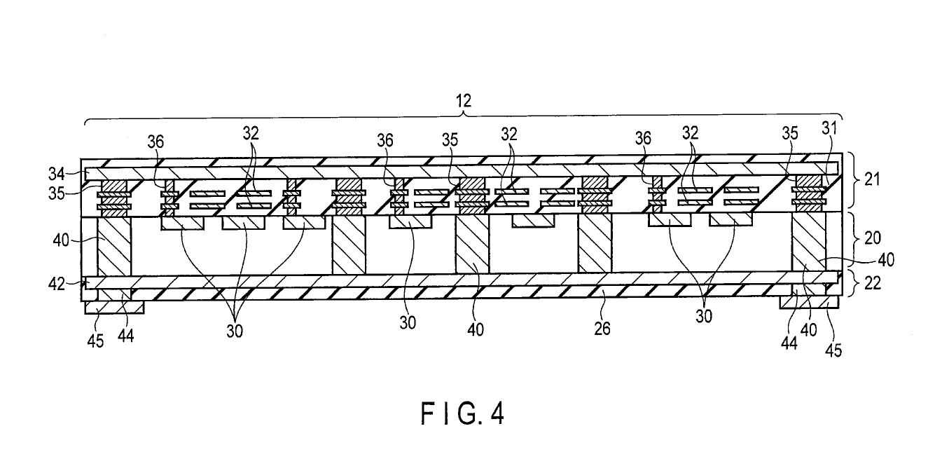

FIG. 1 is a layout of the front side of a solid-state imaging device 10 according to the first embodiment. FIG. 2 is a layout of the backside of the solid-state imaging device 10. FIG. 3 is a sectional view of the solid-state imaging device 10 taken along line A-A′ of FIGS. 1 and 2. FIG. 4 is a sectional view of the solid-state imaging device 10 taken along line B-B′ of FIGS. 1 and 2. The front side of the solid-state imaging device 10 corresponds to one of the opposing first and second principal surfaces of a semiconductor substrate on which a semiconductor element is formed. Accordingly, the backside of the solid-state imaging device 10 corresponds to the other of the first and second principal surfaces. In the first embodiment, light enters through the back surface of the semiconductor substrate.

The solid-state imaging device 10 comprises a pixel area 11 including a pixel unit (pixel array) and a peripheral circuit area 12 including a peripheral circuit for driving and controlling the pixel unit. The pixel area 11 includes a light-receiving area 11A and an optical black area (OB area) 11B. The peripheral circuit area 12 includes an analog circuit and a logic circuit and is formed to surround the pixel area 11, for example.

The solid-state imaging device 10 comprises a semiconductor substrate 20 having a first principal surface (front side) and a second principal surface (backside) opposite to the first principal surface. The semiconductor substrate 20 is formed of a silicon (Si) substrate, for example; however, it can be formed of an epitaxial layer (semiconductor layer) that is made of silicon (Si). A front side interconnection layer 21 is formed on the front surface of the semiconductor substrate 20 and a backside interconnection layer 22 is formed on the back surface of the semiconductor substrate 20. The front side interconnection layer 21 includes a multilevel interconnection layer and an interlayer insulating layer 31. The backside interconnection layer 22 includes lines, a light shielding film 27 and a planarization layer 26. The structures of the front side interconnection layer 21 and the backside interconnection layer 22 will specifically be described later.

The pixel area 11 of the semiconductor substrate 20 includes a plurality of light-receiving elements 23. Each of the light-receiving elements 23 is a photoelectric conversion element that is formed chiefly of a photodiode to convert received light into an electrical signal. The planarization layer 26 is provided on the back surface of the semiconductor substrate 20. A plurality of color filters 24 are provided on the planarization layer 26 and a plurality of microlenses 25 are provided on their respective color filters 24. A light-receiving element 23, a color filter 24 and a microlens 25 make up a single light-receiving cell (pixel). A number of light-receiving cells are arranged in array in the pixel area 11 (light-receiving area 11A and optical black area 11B).

In the optical black area 11B, the light-shielding film 27 is formed on the back surface of the semiconductor substrate 20. The light-shielding film 27 shields light from the back surface of the substrate. The optical black area 11B is used to measure a dark current of the light-receiving elements. The light-shielding film 27 is made of metal having the light-shielding characteristic, such as aluminum (Al) and copper (Cu).

A metal oxide semiconductor field effect transistor (MOSFET) group 30 including a plurality of MOSFETs is provided in the peripheral circuit area 12 and on the front surface of the semiconductor substrate 20. The MOSFET group 30 is combined with front side signal lines (described later) to form a peripheral circuit such as a logic circuit and an analog circuit.

The front side interconnection layer 21 is formed on the front surface of the semiconductor substrate 20 and includes the interlayer insulating layer 31, and the multilevel interconnection layer which is formed in the interlayer insulating layer 31. The front side interconnection layer 21 includes a plurality of signal lines 32, a plurality of front side VDD lines 33 and a plurality of front side VSS lines 34. These lines are made of metal such as aluminum (Al) and copper (Cu). The signal lines 32 are connected to the MOSFET group 30 to form a peripheral circuit such as a logic circuit and an analog circuit. In the pixel area 11, the signal lines 32 are connected to the light-receiving elements 23 and the MOSFET group 30 to transfer signals from the light-receiving elements 23 to the peripheral circuit.

As illustrated in FIG. 1, the front side VDD lines 33 are arranged on both sides of the pixel area 11 in the X direction and extend in the Y direction to the vicinity of both sides of the semiconductor substrate 20. Similarly, the front side VSS lines 34 are arranged on both sides of the pixel area 11 in the X direction and extend in the Y direction to the vicinity of both sides of the semiconductor substrate 20. The front side VDD lines 33 and front side VSS lines 34 are power lines for applying power to the MOSFET group 30. A power supply voltage VDD is applied to the front side VDD lines 33, and a ground voltage VSS is applied to the front side VSS lines 34. The power supply voltage VDD is, for example, 1.5 V and the ground voltage VSS is, for example, 0 V.

In the peripheral circuit area 12, a plurality of through electrodes 40 are provided in the semiconductor substrate 20 to pass through the semiconductor substrate 20. The through electrodes 40 are provided to connect the front side interconnection layer 21 and the backside interconnection layer 22 electrically. The through electrodes 40 are made of a high-concentration impurity semiconductor such as polysilicon or metal such as aluminum (Al) and copper (Cu).

The front side VDD lines 33 are each electrically connected to one end of a corresponding through electrode 40 through a via plug 35. Also, the front side VDD lines 33 are each electrically connected to its corresponding MOSFET 30 through a via plug 36. Similarly, the front side VSS lines 34 are each electrically connected to one end of a corresponding through electrode 40 through a via plug 35. Also, the front side VSS lines 34 are each electrically connected to its corresponding MOSFET 30 through a via plug 36.

A plurality of backside VDD lines 41 and a plurality of backside VSS lines 42 are provided on the back surface of the semiconductor substrate 20 and in the peripheral circuit area 12. As illustrated in FIG. 2, the backside VDD lines 41 are arranged on both sides of the pixel area 11 in the X direction and extend in the Y direction to the vicinity of both sides of the semiconductor substrate 20. Similarly, the backside VSS lines 42 are arranged on both sides of the pixel area 11 in the X direction and extend in the Y direction to the vicinity of both sides of the semiconductor substrate 20. The backside VDD lines 41 and backside VSS lines 42 are power lines for applying power to the MOSFET group 30. A power supply voltage VDD is applied to the backside VDD lines 41, and a ground voltage VSS is applied to the backside VSS lines 42. In the embodiment shown in FIG. 2, the backside VSS line 42 adjacent to the pixel area 11 is formed to surround the pixel area 11.

The backside VSS lines 42 are each electrically connected to the other end of the through electrode 40 and electrically connected to a corresponding front side VSS line 34 via the through electrode 40. Likewise, the backside VDD lines 41 are each electrically connected to a corresponding front side VDD line 33 via the through electrode 40. The backside VDD lines 41 and the backside VSS lines 42 are formed of a metal layer of the same level as the light-shielding film 27.

The backside VSS lines 42 are electrically connected to VSS pads 45 provided on the backside interconnection layer 22 through via plugs 44. Likewise, the backside VDD lines 41 are electrically connected to VDD pads 46 provided on the backside interconnection layer 22 through the via plugs. The signal lines 32 included in the front side interconnection layer 21 are electrically connected to signal pads 47 provided on the backside interconnection layer 22 via the through electrodes 40. The signal pads 47 are provided to transmit or receive an electrical signal to or from an external device, and the VSS pads 45 and VDD pads 46 are provided to receive power from an external device. The electrode pads (VSS pads 45, VDD pads 46 and signal pads 47) are arranged in the peripheral circuit area 12, especially on two of the four sides of the semiconductor substrate 20, namely, both sides of the substrate 20 in the X direction.

Note that although the backside VSS lines 42 are separated from light-shielding film 27 in FIG. 3, they can be connected each other.

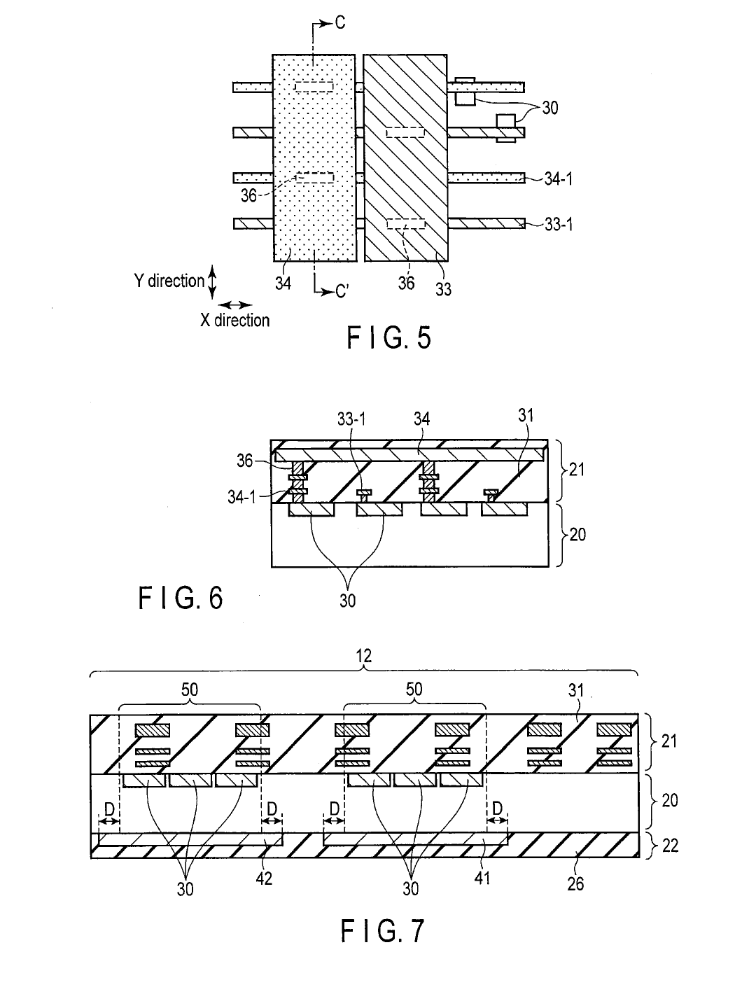

FIG. 1 shows only the main lines of the front side VDD lines and front side VSS lines. It is desirable to form the main lines using an interconnection layer of the front side interconnection layer 21, the interconnection resistance of which is the lowest. Usually, the topmost interconnection layer of the front side interconnection layer 21, which is farthest from the semiconductor substrate 20, can be increased in its width and thickness; thus, its interconnection resistance is the lowest. FIG. 5 is a layout showing the front side interconnection layer 21 in detail. FIG. 6 is a sectional view of the front side interconnection layer 21 taken along line C-C′ of FIG. 5.

As shown in FIGS. 5 and 6, the front side VDD lines 33 and front side VSS lines 34 are formed of the topmost interconnection layers and extend in the Y direction. The lowermost line 33-1 connected to the front side VDD line 33 is provided under the front side VDD line 33. The lowermost line 34-1 connected to the front side VSS line 34 is provided under front side VSS line 34. The lowermost lines 33-1 and 34-1 are formed of the lowermost lines of the front side interconnection layer 21 and extend in the X direction perpendicular to the Y direction.

The front side VSS line 34 is electrically connected to the lowermost line 34-1 through the via plug 36, and the lowermost line 34-1 is electrically connected to the MOSFET 30 through the via plug. Likewise, the front side VDD line 33 is electrically connected to the lowermost line 33-1 through the via plug 36, and the lowermost line 33-1 is electrically connected to the MOSFET 30 through the via plug. Therefore, power is applied to the MOSFET 30 in the peripheral circuit area 12 through the lowermost lines 33-1 and 34-1.

The interconnection structure according to the first embodiment will be described.

The through electrodes 40 are formed right above all of the electrode pads (VSS pads 45, VDD pads 46 and signal pads 47) arranged on the back surface of the semiconductor substrate 20 and both sides of the semiconductor substrate 20 in the X direction. The VSS pads 45, VDD pads 46 and signal pads 47 are electrically connected to the lines in the front side interconnection layer 21 and those in the backside interconnection layer 22. More specifically, the VDD pads 46 are electrically connected to the front side VDD lines 33 and the backside VDD lines 41. The VSS pads 45 are electrically connected to the front side VSS lines 34 and the backside VSS lines 42. The signal pads 47 are electrically connected to the signal lines 32.

The front side and backside VDD lines 33 and 41 overlapping in a planar view are paired to extend in the Y direction. The planar shape of the paired lines 33 and 41 is rectangular. The paired lines 33 and 41 are electrically connected to each other via the through electrodes 40 in their end portions. Furthermore, the paired lines 33 and 41 are electrically connected to each other via one or more through electrodes 40 in their middle portions. Likewise, the front side and backside VSS lines 34 and 42 overlapping in a planar view are paired to extend in the Y direction. The planar shape of the paired lines 34 and 42 is rectangular. The paired lines 34 and 42 are electrically connected to each other via the through electrodes 40 in their end portions. Furthermore, the paired lines 34 and 42 are electrically connected to each other via one or more through electrodes 40 in their middle portions.

As illustrated in FIG. 2, an area between the electrode pads and the pixel area 11 of the back surface of the peripheral circuit area 12 is covered with the backside VSS line 42. In general, the backside VDD lines 41 and backside VSS lines 42 are formed to cover the peripheral circuit area 12. The portions of the back surface of the peripheral circuit area 12 which are not covered with any interconnection layer are the minimum space for electrical isolation, such as a space between the backside VDD line 41 and the backside VSS line 42, a space between the backside VDD line 41 and the signal pad 47 and a space between the backside VSS line 42 and the signal pad 47. For example, it is desirable that not less than 90% of the MOSFETs included in the peripheral circuit area 12 should be covered with the backside lines.

(Advantages)

As described in detail, according to the first embodiment, power can be applied to a MOSFET distant from the VSS and VDD pads 45 and 46 (e.g., a MOSFET located in the middle part of the semiconductor substrate 20), through two routes of the front surface and back surface of the semiconductor substrate 20. Thus, a lower-resistance power supply route can be achieved, as compared with a case where power is applied only through the front surface of the substrate, for example. Moreover, the power lines (VDD and VSS lines) can be decreased in resistance. Accordingly, the power of the solid-state imaging device 10 can be stabilized.

The front side VDD lines 33 and front side VSS lines 34 are formed of an interconnection layer whose line resistance is the lowest, such as a topmost interconnection layer. Therefore, the power lines can be more decreased in resistance.

The backside power lines (backside VDD lines 41 and backside VSS lines 42) are formed to cover most of the back surface of the peripheral circuit area 12. Accordingly, most of the MOSFETs of the peripheral circuit area 12 can be shielded from light. When the MOSFETs are irradiated with light, a leakage current is generated from the MOSFETs due to photoelectric conversion. In the first embodiment, however, most of the MOSFETs of the peripheral circuit area 12 are shielded from light, with the result that the amount of leakage current generated from the MOSFETs can be reduced and accordingly the power consumption of the solid-state imaging device 10 can greatly be reduced.

Since the backside power lines are formed of a metal layer of the same level as the light-shielding layer 27, the backside power lines and the light-shielding layer 27 can be formed at once in the same step. Therefore, the backside power lines can be formed without any additional steps, as compared with a case where only the light-shielding layer 27 is formed.

### Second Embodiment

In the second embodiment, a plurality of MOSFETs 30 included in a peripheral circuit area 12 are arranged to overlap backside VDD lines 41 and backside VSS lines 42 in a planar view; thus, irradiating the MOSFETs 30 with light is decreased further. The solid-state imaging device 10 of the second embodiment differs from that of the first embodiment only in the locations of the MOSFETs 30 and they are the same in the other respects. Only the structure of the second embodiment which differs from that of the first embodiment will be described.

FIG. 7 is a sectional view of the peripheral circuit area 12 according to the second embodiment. The MOSFETs 30 included in the peripheral circuit area 12 are arranged in an area (MOSFET forming area) provided inside each of the backside VDD lines 41 by distance D from both ends of the pattern (width) of each of the backside VDD lines 41. In other words, in a planar view, no MOSFETs are arranged in an area where the backside VDD lines 41 are not formed and an area provided within distance D from both ends of each of the backside VDD lines 41 in the width direction. Likewise, the MOSFETs 30 included in the peripheral circuit area 12 are arranged in an area (MOSFET forming area) provided inside each of the backside VSS lines 42 by distance D from both ends of the pattern (width) of each of the backside VSS lines 42. In other words, in a planar view, no MOSFETs are arranged in an area where the backside VSS lines 42 are not formed and an area provided within distance D from both ends of each of the backside VSS lines 42.

The distance D is, for example, about 10 μm to 500 μm in terms of a design value determined based on the specification (stability, power consumption, etc.) required for the peripheral circuit.

According to the second embodiment, all of the MOSFETs 30 included in the peripheral circuit area 12 can be shielded from light. The MOSFETs 30 are also arranged in positions where light is harder to apply in accordance with the specification required for the peripheral circuit. Therefore, as compared with the first embodiment, the operation of the MOSFETs 30 can be performed more stably and the leakage current of the MOSFETs 30 due to photoelectric conversion can be reduced further.

### Third Embodiment

In the third embodiment, an interconnection layer having the light-shielding characteristic is formed on the entire back surface of a peripheral circuit area 12 and thus light incident upon a plurality of MOSFETs 30 included in the peripheral circuit area 12 can be more reduced.

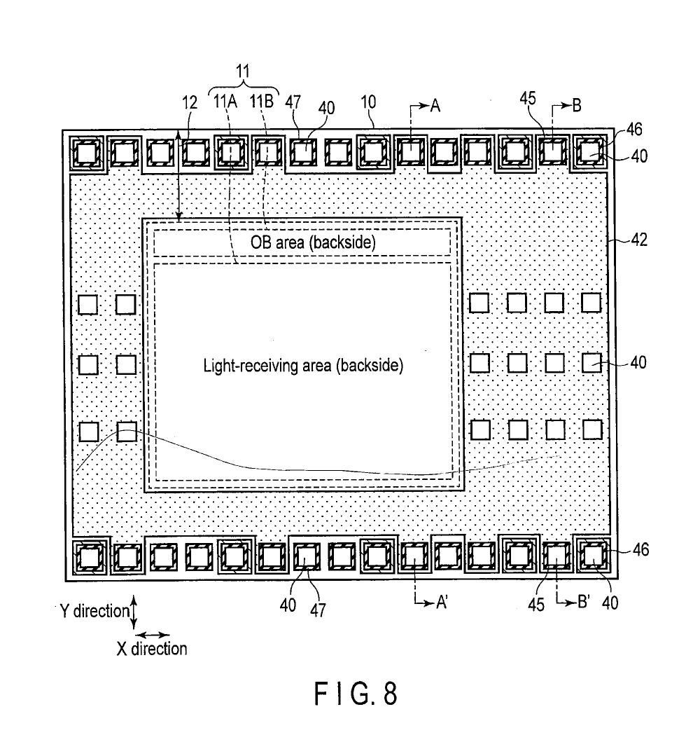

FIG. 8 is a layout of the backside of a solid-state imaging device 10 according to the third embodiment. The layout of the front side of the solid-state imaging device 10, the sectional view thereof taken along line A-A′ and the sectional view thereof taken along line B-B′ are the same as those of FIGS. 1, 3 and 4 of the first embodiment.

A backside VSS line 42 is provided on almost all the back surface of the peripheral circuit area 12. More specifically, the backside VSS line 42 is formed on all the peripheral circuit area 12 except an area where VDD pads 46 and signal pads 47 are arranged. In the third embodiment, a backside interconnection layer 22 includes only the backside VSS line 42 and not a backside VDD line for a power line. The structures of front side VDD and VSS lines 33 and 34 included in a front side interconnection layer 21 are the same as those in the first embodiment.

According to the third embodiment, all the MOSFETs 30 included in the peripheral circuit area 12 are covered with the backside VSS line 42. Thus, light incident upon all the MOSFETs 30 included in the peripheral circuit area 12 can be more reduced. Unlike in the second embodiment, in the third embodiment, the arrangement of the MOSFETs 30 included in the peripheral circuit area 12 need not be controlled, but the MOSFETs 30 can freely be formed in the peripheral circuit area 12.

In place of the backside VSS line 42, the backside VDD line 41 can be formed on the entire back surface of the peripheral circuit area 12.

In the above embodiments, the electrode pads (VSS pads, VDD pads and signal pads) are provided on the opposing two sides of a rectangular semiconductor substrate. The above embodiments are not limited to this. The electrode pads can be provided on all of the four sides of the rectangular semiconductor substrate.

The interconnection structure of the above embodiments is not limited to the power lines but can be applied to signal lines for transmission of signals.

The power lines of the above embodiments can be applied to a semiconductor device (semiconductor integrated circuit) other than the solid-state imaging device.

### APPLICATION EXAMPLE

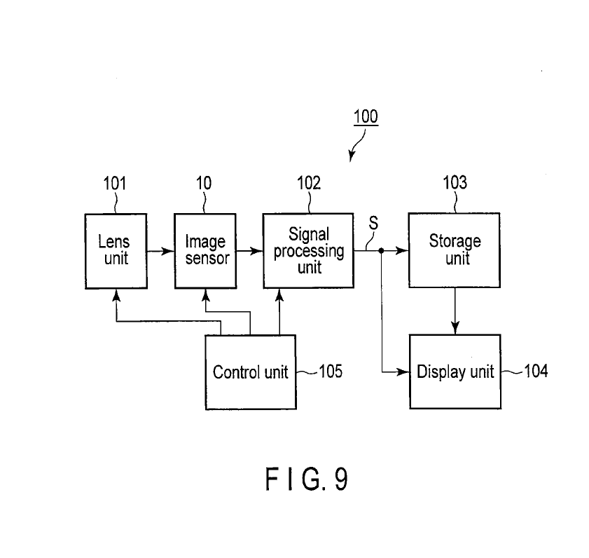

The solid-state imaging device 10 described in each of the above embodiments is applicable to a digital camera or various electronic devices equipped with a camera such as a cellular phone with camera. FIG. 9 is a block diagram of a digital camera 100 using the solid-state imaging device 10 according to the embodiment.

The digital camera 100 comprises a lens unit 101, the solid-state imaging device (image sensor) 10, a signal processing unit 102, a storage unit 103, a display unit 104, and a control unit 105.

The lens unit 101 includes a plurality of imaging lenses, and mechanically or electrically controls the optical characteristics (for example, focal length) for incident light. The light that has passed through the lens unit 101 forms an image on the image sensor 10. An electrical signal output from the image sensor 10 is processed by the signal processing unit 102. The signal processing unit 102 is formed from a digital signal processor (DSP) or the like. A signal S from the signal processing unit 102 is output to the display unit 104 or output to the display unit 104 via the storage unit 103. The image that is captured or being captured is thus displayed on the display unit 104. The control unit 105 controls the operation of the entire digital camera 100, and also controls the operation timings of the lens unit 101, the image sensor 10, and the signal processing unit 102.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a semiconductor substrate including a pixel area and a peripheral circuit area and having a first principal surface and a second principal surface;
a first line provided in the peripheral circuit area and on the first principal surface of the semiconductor substrate and extending in a first direction;
a second line provided in the peripheral circuit area and on the second principal surface of the semiconductor substrate and extending in the first direction;
a first through electrode connected to one end of the first line and one end of the second line and passing through the semiconductor substrate; and
a second through electrode connected to the other end of the first line and the other end of the second line and passing through the semiconductor substrate.

2. The device of claim 1, further comprising a third through electrode connected to middle portions of the first line and the second line and passing through the semiconductor substrate.

3. The device of claim 1, wherein
the first line and the second line extend to opposing two sides of the semiconductor substrate, and
the first through electrode and the second through electrode are arranged on the opposing two sides of the semiconductor substrate.

4. The device of claim 1, further comprising:
a first electrode pad provided on the second principal surface of the semiconductor substrate and on the first through electrode; and
a second electrode pad provided on the second principal surface of the semiconductor substrate and on the second through electrode.

5. The device of claim 1, further comprising MOSFETs provided in the peripheral circuit area and on the first principal surface of the semiconductor substrate, some of the MOSFETs being covered with the second line in a planar view.

6. The device of claim 1, wherein the first line and the second line are power lines.

7. The device of claim 1, further comprising:
light-receiving elements provided in the pixel area and on the second principal surface of the semiconductor substrate; and
a light-shielding film provided in the pixel area and on the second principal surface of the semiconductor substrate to cover some of the light-receiving elements in a planar view,
wherein the light-shielding film is formed of a metal layer of the same level as the second line.

8. A solid-state imaging device comprising:
a semiconductor substrate including a pixel area and a peripheral circuit area and having a first principal surface and a second principal surface;
first lines provided in the peripheral circuit area and on the first principal surface of the semiconductor substrate and extending in a first direction;
second lines provided in the peripheral circuit area and on the second principal surface of the semiconductor substrate and extending in the first direction;
first through electrodes each connected to one end of a corresponding one of the first lines and one end of a corresponding one of the second lines and passing through the semiconductor substrate; and
second through electrodes each connected to the other end of the corresponding one of the first lines and the other end of the corresponding one of the second lines and passing through the semiconductor substrate.

9. The device of claim 8, further comprising third through electrodes connected to respective middle portions of the first lines and respective middle portions of the second lines and passing through the semiconductor substrate.

10. The device of claim 8, wherein
the first lines and the second lines extend to opposing two sides of the semiconductor substrate, and
the first through electrodes and the second through electrodes are arranged on the opposing two sides of the semiconductor substrate.

11. The device of claim 8, further comprising:
first electrode pads provided on the second principal surface of the semiconductor substrate and on the first through electrodes, respectively; and
second electrode pads provided on the second principal surface of the semiconductor substrate and on the second through electrodes, respectively.

12. The device of claim 8, further comprising MOSFETs provided in the peripheral circuit area and on the first principal surface of the semiconductor substrate, some of the MOSFETs being covered with the second lines in a planar view.

13. The device of claim 8, wherein the first lines and the second lines are power lines.

14. The device of claim 8, further comprising:
light-receiving elements provided in the pixel area and on the second principal surface of the semiconductor substrate; and
a light-shielding film provided in the pixel area and on the second principal surface of the semiconductor substrate to cover some of the light-receiving elements in a planar view,
wherein the light-shielding film is formed of a metal layer of the same level as the second lines.

15. A semiconductor device comprising:
a semiconductor substrate having a first principal surface and a second principal surface;
MOSFETs provided on the first principal surface of the semiconductor substrate;
a first line provided on the first principal surface of the semiconductor substrate, extending in a first direction, and connected to one of the MOSFETs;
a second line provided on the second principal surface of the semiconductor substrate and extending in the first direction;
a first through electrode connected to one end of the first line and one end of the second line and passing through the semiconductor substrate; and
a second through electrode connected to one end of the first line and one end of the second line and passing through the semiconductor substrate.

16. The device of claim 15, further comprising a third through electrode connected to middle portions of the first line and the second line and passing through the semiconductor substrate.

17. The device of claim 15, wherein
the first line and the second line extend to opposing two sides of the semiconductor substrate, and
the first through electrode and the second through electrode are arranged on the opposing two sides of the semiconductor substrate.

18. The device of claim 15, further comprising:
a first electrode pad provided on the second principal surface of the semiconductor substrate and on the first through electrode; and
a second electrode pad provided on the second principal surface of the semiconductor substrate and on the second through electrode.

19. The device of claim 15, wherein some of the MOSFETs is covered with the second line in a planar view.

20. The device of claim 15, wherein the first line and the second line are power lines.
